(19) United States
(12) Patent Application Publication
(10) Pub. No.: US 2013/0104972 A1
(43) Pub. Date: May 2, 2013

(54) Se OR S BASED THIN FILM SOLAR CELL AND METHOD OF MANUFACTURING THE SAME

(71) Applicants: Jeung Hyun JEONG, Seoul (KR); Ju Heon YOON, Seoul (KR); Won Mok KIM, Seoul (KR); Young Joon BAIK, Seoul (KR); Jong Keuk PARK, Seoul (KR)

(72) Inventors: Jeung Hyun JEONG, Seoul (KR); Ju Heon YOON, Seoul (KR); Won Mok KIM, Seoul (KR); Young Joon BAIK, Seoul (KR); Jong Keuk PARK, Seoul (KR)

(73) Assignee: KOREA INSTITUTE OF SCIENCE AND TECHNOLOGY, Seoul (KR)

(21) Appl. No.: 13/563,915

(22) Filed: Aug. 1, 2012

(30) Foreign Application Priority Data
Oct. 26, 2011 (KR) 10-2011-0109770

(51) Int. Cl. H01L 31/0224; H01L 31/18

(52) U.S. Cl. 136/256; 438/94; 257/E31.027

(57) ABSTRACT

Provided is a Se- or S-based thin film solar cell, including a substrate, a rear electrode formed on the substrate, a light absorbing layer formed on the rear electrode and containing at least one of selenium (Se) and sulfur (S), and an rear electrode top layer. The rear electrode top layer is formed between the rear electrode and the light absorbing layer, and contains a large amount of oxygen (O) to control diffusion of sodium (Na) through the rear electrode to the light absorbing layer. In this manner, it is possible to improve the electrical conductivity and interfacial adhesion of the rear electrode while stimulating diffusion of sodium (Na) to improve the efficiency of a thin film solar cell.

### CROSS-REFERENCE TO RELATED APPLICATION

This application claims priority to Korean Patent Application No. 2011-0109770, filed on Oct. 26, 2011, and all the benefits accruing therefrom under 35 U.S.C. §119, the contents of which in its entirety are herein incorporated by reference.

### BACKGROUND

1. Field

The present disclosure relates to a thin film solar cell and a method for manufacturing the same. More particularly, the present disclosure relates to a Se- or S-based thin film solar cell containing selenium (Se) or sulfur (S) and a method for manufacturing the same.

2. Description of the Related Art

Se- or S-based thin film solar cells using Cu(In₁₋ₓ,Gaₓ)(Se,S)₂ (CIGS), Cu₂ZnSn(Se,S)₄ (CZTS) or the like as a light absorbing layer are expected to be the next generation economical high-efficiency solar cells by virtue of their high ability of light absorption, excellent carrier transport properties, and low cost fabrication.

Particularly, copper-indium-gallium-selenide (CIGS) solar cells may provide high-efficiency solar cells not only on transparent glass but also on flexible substrates, such as stainless steel or titanium, and polyimide (PI). Thus, it is expected that such flexible substrate technologies enable substantial reduction of manufacturing cost through a roll-to-roll process, reduce balance-of-system (BOS) accruing from their low weight and high durability, and diversify the range of applications to Building Integrated Photovoltaic Systems (BIPS) and various portable energy sources.

Addition of sodium (Na) to a CIGS thin film increases the hole concentration of CIGS, while providing an improved open circuit voltage (Voc) and fill factor (FF) to increase photovoltaic conversion efficiency significantly. Although it is not clearly known how sodium (Na) plays a role in such an increase in efficiency, it appears that the hole carrier concentration is increased by passivation of a deep-level donor defects in CIGS or the like, or by forming an additional acceptor level.

Sodium (Na) not only improves electronic properties per se but also affects the microstructure (grain size, preferential orientation) of a CIGS thin film and diffusion rates of gallium (Ga) and indium (In), thereby determining the efficiency of a solar cell significantly. Therefore, doping of an adequate amount of sodium (Na) is very important for high efficiency of a CIGS solar cell. Particularly, in the case of a large-area module, non-homogeneous doping of sodium (Na) may results in significant loss in efficiency.

Accordingly, various methods for supplying sodium (Na) have been proposed. Among those, use of a soda lime glass substrate and deposition of a sodium (Na) layer prior to the deposition of a rear electrode are advisable in view of simplification of a manufacturing process and improvement of reproducibility, since sodium (Na) into a CIGS thin film can be controlled more easily through the rear electrode from the back surface of the rear electrode during the deposition of the CIGS thin film at high temperature. Herein, in the case of a soda lime glass substrate used frequently as a substrate, it likely shows high non-uniformity of Na content, and thus may cause inhomogeneous Na doping in a CIGS absorbing layer.

However, in this case, sodium (Na) has to pass through the rear electrode, and thus a degree of diffusion of sodium (Na) is affected significantly by the microstructure of the rear electrode.

Molybdenum (Mo) has been used as a rear electrode of a CIGS solar cell. Since a CIGS thin film is deposited at a high temperature of 500° C. or higher, high-temperature stability is required for a rear electrode. In this regard, molybdenum (Mo) has been used as a rear electrode by virtue of its excellent heat resistance, electrically ohmic contact formation with a CIGS film, high electrical conductivity and excellent interfacial adhesion with a substrate through control of a microstructure.

A molybdenum (Mo) thin film is formed by a vacuum deposition process, such as sputtering. Due to low molybdenum (Mo) atom mobility, it is possible to control the Mo thin film to have various microstructures, such as from a highly packed to highly porous, etc., depending on the magnitude of energy of deposited particles. Typically, when increasing deposition pressure, collision among particles increases and particle energy decreases, and thus the grain size of polycrystalline Mo films decreases while porosity increases gradually. Accordingly, residual stress is converted from compressive to tensile and electrical conductivity also decreases.

There are two basic functions of a rear electrode: excellent interfacial adhesion with a substrate and high electrical conductivity. To improve the interfacial adhesion of a molybdenum (Mo) thin film, it is required to minimize residual stress, which loosens the atomic structure, resulting in a reduction in electrical conductivity.

Therefore, to satisfy the two functions at the same time, a bilayer rear electrode is used, and such an electrode is obtained by depositing a first molybdenum layer having a microstructure provided with high electrical resistance but high porosity so that impact may be relaxed upon the application of external force, and then depositing a more dense second molybdenum layer having lower electrical resistance. Such a bilayer rear electrode is disclosed in U.S. Pat. No. 6,258,620, and the conditions and thicknesses of the deposition of the first electrode layer and the second electrode layer are disclosed in Korean Patent No. 10-0743923.

The bilayer rear electrode is advisable in terms of interfacial adhesion and electroconductivity, but it is not optimized in terms of sodium (Na) diffusion. Under high electrical conductivity, molybdenum (Mo) has a very dense microstructure, making it difficult to perform sodium (Na) diffusion.

Therefore, it is necessary to control the microstructure of molybdenum (Mo) in such a manner that a sodium (Na) diffusion rate may be tunable and at the same time homogeneous Na doping may be guaranteed regardless of the Na content of a Na supplying layer, while not adversely affecting the interfacial adhesion and electrical conductivity of a molybdenum (Mo) thin film. Such an approach will contribute to improvement of the solar cell efficiency.

### SUMMARY

The present disclosure is directed to providing a Se- or S-based thin film solar cell capable of realizing improved efficiency by controlling sodium (Na) diffusion and allowing homogeneous Na doping.

The present disclosure is also directed to providing a method for manufacturing the Se- or S-based thin film solar cell.

In one aspect, there is provided a Se- or S-based thin film solar cell, including: a substrate; a rear electrode formed on the substrate; a light absorbing layer formed on the rear electrode and containing at least one of selenium (Se) and sulfur (S); and an rear electrode top layer formed between the rear electrode and the light absorbing layer and containing oxygen (O) to control diffusion of sodium (Na) from the rear electrode to the light absorbing layer.

According to an embodiment, the rear electrode may have a dense microstructure by application of high compressive residual stress thereto, and the rear electrode top layer may have a microstructure with higher porosity than the rear electrode, wherein the porosity may be 0.1-20%.

According to an embodiment, the rear electrode may have a dense microstructure by application of high compressive residual stress thereto, and the rear electrode top layer may have an oxygen content of 1-20 at %.

According to an embodiment, the rear electrode top layer may have a higher sodium (Na) content than the rear electrode.

According to an embodiment, the light absorbing layer may include any one of Cu(In₁₋ₓ, Gaₓ)(Se,S)₂ (CIGS) as a I-III-VI₂ semiconductor compound and Cu₂ZnSn(Se,S)₄ (CZTS) as a I₂-II-IV-VI₄ semiconductor compound.

According to an embodiment, the rear electrode top layer may include a metal (M) that reacts with selenium (Se) of the light absorbing layer to form a compound of MₓSe_{y}.

According to an embodiment, the rear electrode or the rear electrode top layer may include any one of molybdenum (Mo), nickel (Ni), tungsten (W), cobalt (Co), titanium (Ti), copper (Cu) and gold (Au), or an alloy thereof.

According to an embodiment, the rear electrode may be in a single layer or bilayer structure.

According to an embodiment, the substrate may be formed of any one of transparent insulating materials, metals, and polymers. In this case, the substrate may include a metal, such as stainless steel or titanium (Ti), and the thin film solar cell may further include a diffusion barrier film and a sodium (Na) precursor layer between the substrate and the rear electrode. The diffusion barrier film may be formed of any one selected from silicon oxide (SiOₓ), aluminum oxide (Al₂O₃), chrome (Cr), zinc oxide (ZnO) and nitride thin films. The sodium (Na) precursor layer may be formed of any one selected from sodium (Na)-doped molybdenum (Mo), sodium fluoride (NaF), soda lime glass and alkali silicate glass thin films.

According to an embodiment, the thin film solar cell may further include a first semiconductor layer, a second semiconductor layer and a transparent electrode layer formed on the light absorbing layer.

In another aspect, there is provided a method for manufacturing a Se- or S-based thin film solar cell, including: forming a rear electrode on a substrate; forming an rear electrode top layer containing oxygen (O) on the rear electrode; and forming a light absorbing layer containing at least one of selenium (Se) and sulfur (S) on the rear electrode top layer.

According to an embodiment, the operation of forming an rear electrode top layer may be carried out by depositing a molybdenum (Mo) thin film having a porosity of 0.1-20% so that the rear electrode top layer may have a microstructure with higher porosity than the rear electrode.

According to an embodiment, the operation of forming a rear electrode top layer may be carried out under argon atmosphere of 8-40 mTorr to a thickness of 1-100 nm or 1-50 nm.

According to an embodiment, the operation of forming a rear electrode top layer may be carried out by oxidizing the surface of the rear electrode. In this case, to oxidize the surface of the rear electrode, the rear electrode may be exposed to oxygen plasma under vacuum or may be subjected to heat treatment under oxygen atmosphere.

According to an embodiment, the operation of forming a rear electrode may further include forming a stress-relaxing buffer layer on the substrate.

According to an embodiment, when the substrate includes a metal, the method may further include, before forming the rear electrode, forming a diffusion barrier film on the substrate, and forming a sodium (Na) precursor layer on the diffusion barrier film.

According to an embodiment, the method for manufacturing a thin film solar cell may further include stacking a first semiconductor layer, a second semiconductor layer and a transparent electrode layer sequentially on the light absorbing layer.

According to the Se- or S-based thin film solar cell and the method for manufacturing the same disclosed herein, it is possible to realize a rear electrode structure in such a manner that electrical conductivity, interfacial adhesion and sodium (Na) diffusion controllability required for a rear electrode may be satisfied at the same time by introducing an rear electrode top layer containing a large amount of oxygen to a rear electrode.

In addition, since a rear electrode having higher density than the typical rear electrode of a solar cell according to the related art may be formed, it is possible to reduce non-uniformity of sodium (Na) diffusion and at the same time to ensure the stability of a rear electrode at high temperature.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a sectional view of a thin film solar cell according to an embodiment;

FIG. 2 is a graph illustrating the depth profiles of sodium (Na) concentration, as measured by dynamic secondary ion mass spectroscopy (D-SIMS), depending on deposition conditions of a rear electrode of a thin film solar cell of FIG. 1;

FIG. 3 is a graph illustrating the depth profiles of sodium (Na) concentration, as dynamic secondary ion mass spectroscopy (D-SIMS), depending on surface microstructures of a rear electrode of a thin film solar cell of FIG. 1;

FIG. 4 is a graph illustrating the depth profiles of sodium (Na) concentration, as measured by dynamic secondary ion mass spectroscopy (D-SIMS), depending on surface oxidation of a rear electrode of a thin film solar cell of FIG. 1;

FIG. 5 is a graph illustrating efficiency depending on surface microstructures of a rear electrode of a thin film solar cell of FIG. 1; and

FIG. 6 is a sectional view of a thin film solar cell according to another embodiment.

### DETAILED DESCRIPTION

Exemplary embodiments now will be described more fully hereinafter with reference to the accompanying drawings, in which exemplary embodiments are shown.

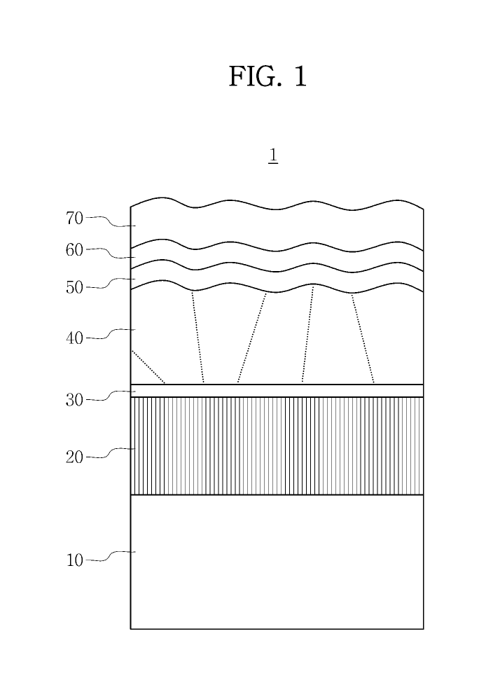

FIG. 1 is a sectional view of a thin film solar cell according to an embodiment.

Referring to FIG. 1, the thin film solar cell 1 according to an embodiment is a Se-based or S-based thin film solar cell, and includes a substrate 10, a rear electrode 20, a rear electrode top layer 30 and a light absorbing layer 40, stacked successively.

The thin film solar cell 1 may further include a first semiconductor layer 50, a second semiconductor layer 60 and a transparent electrode layer 70, stacked on the light absorbing layer 40. The first semiconductor layer 50 and the second semiconductor layer 60 may be formed of an n-type semiconductor.

The substrate 10 may have flexibility and may be formed of a transparent insulating material. For example, the substrate 10 may be formed of soda lime glass.

The soda lime glass contains a large amount of sodium (Na), and then sodium (Na) passes through the rear electrode 20 and diffuses into the light absorbing layer 40, during the subsequent deposition process at high temperature. When the light absorbing layer 40 is doped with sodium (Na) in this manner, the hole concentration in the light absorbing layer 40 increases, while providing an improved open circuit voltage (Voc) and fill factor (FF).

The rear electrode 20 is formed on the substrate 10 and may have a dense microstructure having compressive residual stress. The rear electrode 20 may be formed of a pure metal or alloy that shows high heat resistance at about 400-600° C. and has low electrical resistivity. For example, the rear electrode 20 may be formed of any one selected from molybdenum (Mo), nickel (Ni), tungsten (W), cobalt (Co), titanium (Ti), copper (Cu) and gold (Au), or an alloy thereof.

The rear electrode 20 may be a single layer electrode or bilayer electrode. When the rear electrode 20 is a bilayer electrode (having a first rear electrode layer and a second rear electrode layer), the first rear electrode layer (buffer layer) that is in contact with the substrate may have a highly porous microstructure in view of the interfacial adhesion with the substrate, and the second rear electrode layer may be formed to have a dense microstructure to improve electrical conductivity.

The first rear electrode layer is a thin film having a large number of pores and absorbs external impact by virtue of low residual stress and high porosity, and thus retains the second rear electrode layer deposited thereon more stably. Therefore, under such a bilayer structure of the rear electrode 20, it is possible to control the characteristics of the two layers freely from a very dense microstructure to a highly porous microstructure depending on intended use.

Considering only the electrical conductivity, the most important property for the rear electrode 20, the two layers may have a very dense microstructure. However, considering sodium (Na) diffusion, such a dense microstructure inhibits sodium (Na) diffusion and is not advisable.

To stimulate sodium (Na) diffusion, the rear electrode 20 may have increased porosity. However, in this case, the thin film forming the rear electrode 20 is unstabilized and broken or causes microcracks during a high-temperature process, and consequently sodium (Na) diffusion may be inhomogeneous or uncontrollable.

Therefore, it is required for the rear electrode 20 to ensure a structure and microstructure capable of stimulating diffusion of sodium (Na) into the light absorbing layer 40 and ensuring uniform Na diffusion while maintaining high electroconductivity and interfacial adhesion of the rear electrode 20.

The rear electrode top layer 30 is formed between the rear electrode 20 and the light absorbing layer 40 and may contain a large amount of oxygen (O). It is possible to control the diffusion of sodium (Na) from the rear electrode 20 to the light absorbing layer 40 as a function of the density of the rear electrode top layer 30.

The rear electrode top layer 30 has a microstructure with higher porosity than the rear electrode 20, and the porosity thereof may be about 0.1-20%. In addition, the rear electrode top layer 30 may contain a metal (M) that reacts with selenium (Se) contained in the light absorbing layer 40 to form a compound of MₓSe_{y}.

For example, the metal (M) contained in the rear electrode top layer 30 may be any one selected from molybdenum (Mo), nickel (Ni), tungsten (W), cobalt (Co), titanium (Ti), copper (Cu) and gold (Au), or an alloy thereof. The rear electrode 20 and the rear electrode top layer 30 may contain the same metal. The rear electrode top layer 30 will be described hereinafter.

The light absorbing layer 40 may include selenium (Se) or sulfur (S) as a p-type semiconductor. For example, the light absorbing layer may include any one of Cu(In₁₋ₓ, Gaₓ)(Se,S)₂ (CIGS) as a I-III-VI₂ semiconductor compound and Cu₂ZnSn(Se,S)₄ (CZTS) as a I₂-II-IV-VI₄ semiconductor compound.

The sodium (Na) content in the light absorbing layer 40 is related closely with the microstructure of the rear electrode 20. As the porosity of the rear electrode 20 increases, the sodium (Na) content in the rear electrode 20 increases and the sodium (Na) content in the light absorbing layer 40 also increases.

However, diffusion of sodium (Na) into the light absorbing layer 40 depends largely on the surface condition of the rear electrode 20 rather than the bulk microstructure of the rear electrode 20. Therefore, it is possible to control diffusion of sodium (Na) by modifying the surface properties of the rear electrode 20 so that they facilitate sodium (Na) diffusion.

Since sodium (Na) ions have high chemical affinity with oxygen (O) ions, sodium (Na) diffusion may be stimulated by electron exchange with oxygen (O) ions. Therefore, as the oxygen (O) content present in the rear electrode 20 increases, sodium (Na) diffusion in the rear electrode 20 increases.

However, the sodium (Na) content in the light absorbing layer 40 is not determined merely by the sodium (Na) content of the rear electrode 20 but by the sodium (Na) content present on the surface of the rear electrode 20.

It may be supposed that sodium has such a small particle size that its diffusion may not be significantly affected by the quality of the microstructure of the rear electrode 20 per se, while the surface of the rear electrode 20 is in contact with the light absorbing layer 40, and thus a higher sodium (Na) content on the surface of the rear electrode 20 results in increased diffusion of sodium (Na) into the light absorbing layer 40. Therefore, it is very important to control the oxygen (O) concentration on the surface of the rear electrode 20 adequately.

As shown in FIG. 1, the rear electrode top layer 30 is formed on the rear electrode 20 to control the oxygen (O) concentration on the surface of the rear electrode 20 adequately. It is possible to control the oxygen content depending on density of the rear electrode top layer 30.

The rear electrode top layer 30 may be formed by a surface modified layer having an independently varied oxygen concentration and a very small thickness, or by carrying out surface treatment of the rear electrode 20.

The rear electrode top layer 30 may be formed by depositing a molybdenum (Mo) thin film having a very small thickness and high porosity to control the oxygen (O) content. Otherwise, the rear electrode top layer 30 may be formed by heat treating the rear electrode 20 under oxygen (O) atmosphere or surface treating the rear electrode 20 under various gaseous atmospheres, such as oxygen (O) plasma, or in the presence of liquid oxygen (O). For example, the rear electrode top layer 30 may be formed to a thickness of about 1-100 nm or 1-50 nm under atmosphere of argon of about 8-40 mTorr.

The rear electrode top layer 30 has such a thickness that it is sufficient to control the sodium (Na) content of the light absorbing layer 40 and is maintained at a small thickness capable of minimizing the effect upon the magnitude of electrical resistance or interfacial adhesion of the rear electrode 20.

Therefore, the rear electrode 20 may have an electrically optimized microstructure without considering the control of sodium (Na) diffusion, and thus may be provided with various characteristics independently as compared to the microstructures or characteristics provided according to the related art.

More particularly, the rear electrode 20 may have a very dense structure allowing a significant effect of compressive stress to maximize electrical conductivity, while the rear electrode top layer 30 may contain a large amount of oxygen to maximize sodium (Na) diffusion. As a result, the rear electrode 20 has very low sodium (Na) content, while the rear electrode top layer 30 has very high sodium (Na) content.

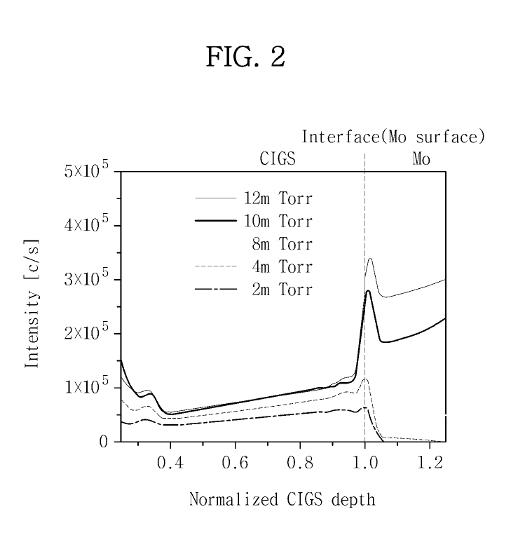

FIG. 2 is a graph illustrating the depth profiles of sodium (Na) concentration, as measured by D-SIMS, depending on deposition conditions of a rear electrode of a thin film solar cell of FIG. 1.

Hereinafter, the thin film solar cell 1 will be explained with reference to an embodiment wherein the substrate 10 is a soda lime glass, the rear electrode 20 is a molybdenum (Mo) thin film, and the light absorbing layer 40 is formed of a CIGS thin film.

In the thin film solar cell 1 of FIG. 1, since the rear electrode 20 is formed between the substrate 10 as a sodium (Na) source and the light absorbing layer 40 requiring sodium (Na), it serves as a path for sodium (Na) diffusion at a processing temperature of 500° C. or higher

Therefore, the microstructure, such as a grain size or porosity, of the rear electrode 20 plays an important role in sodium (Na) diffusion. FIG. 2 shows distribution of sodium (Na) as a function of depth from CIGS surface as determined by dynamic-secondary ion mass spectrometry (D-SIMS) in a CIGS/Mo structure obtained by a three-stage coevaporation process.

The molybdenum (Mo) thin film used as the rear electrode 20 is deposited by a sputtering process, and undergoes a change from a dense microstructure to a loose microstructure as deposition pressure increases. Particularly, the thin film undergoes a rapid increase in thin film porosity under about 10 mTorr or higher. It can be seen that the sodium (Na) content contained in the molybdenum (Mo) thin film increases in proportion to such a microstructural change of the molybdenum (Mo) thin film.

It can be seen that a large amount of sodium (Na) is present near the CIGS/Mo interface (consider the Na peak at the interface). The more the molybdenum (Mo) thin film becomes loose, the higher the sodium (Na) intensity at the interface is. Further, it can be seen that the sodium (Na) content in the CIGS thin film increases in proportion to the Na intensity at the CIGS/Mo interface.

The results in FIG. 2 alone may not reveal the exact physics underlying the effect of the microstructure of the molybdenum (Mo) thin film upon sodium (Na) diffusion. However, they demonstrate that the microstructure of the molybdenum (Mo) thin film significantly affects sodium (Na) diffusion. As deposition pressure increases and as a result the microstructure of the molybdenum (Mo) thin film becomes loose, the amount of sodium (Na) diffused into the CIGS thin film increases.

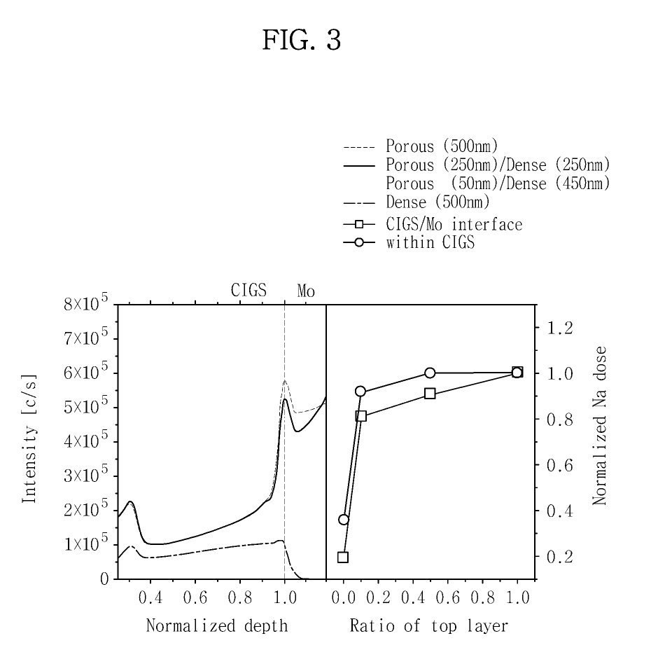

FIG. 3 is a graph illustrating the depth profile of sodium (Na) concentration depending on surface microstructures of a rear electrode of a thin film solar cell of FIG. 1.

FIG. 3 shows that sodium (Na) diffusion is determined by the surface properties of the rear electrode 20 formed of a molybdenum (Mo) thin film. The light absorbing layer 40 formed of a CIGS thin film is deposited by a three-stage coevaporation process, and the molybdenum (Mo) thin film is deposited under such conditions that it has two different types (very dense vs. highly porous) of microstructures.

To determine which of Mo bulk and surface microstructures influences dominantly the sodium diffusion, double-layer molybdenum (Mo) thin film is prepared by using a dense microstructure as a bottom layer and a highly porous microstructure as a top layer. While the relative proportion of the top layer is increased, the ratio of the top layer to the total molybdenum (Mo) thin film is varied to 0, 0.1, 0.5 and 1.0.

In the case of a rear electrode 20 having a microstructure with higher porosity, the sodium (Na) content in molybdenum (Mo) film is higher and sodium (Na) content in CIGS film is also higher. It is particularly noted that the deposition of about 50 nm of highly porous molybdenum on highly dense molybdenum provide the sodium doping of almost the same concentration in CIGS as a rear electrode 20 totally formed of highly porous molybdenum.

FIG. 3 also shows that increasing thickness of top molybdenum (Mo) with high porosity up to about 250 nm causes little change. It can be seen from the above test results that the microstructure of the rear electrode 20 formed of molybdenum (Mo) thin film affects a degree of diffusion of sodium (Na) into a CIGS thin film, but, more specifically, the sodium diffusion depends more largely on the Mo surface properties rather than its bulk properties.

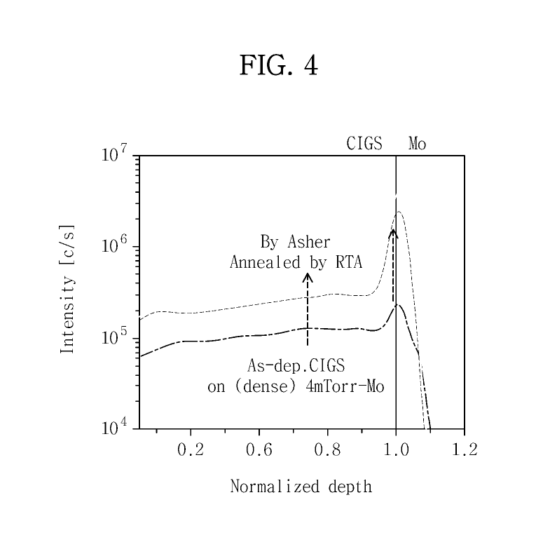

FIG. 4 is a graph illustrating depth profile of sodium (Na) concentration depending on surface oxidation of a rear electrode of a thin film solar cell of FIG. 1.

To reveal how the porous surface of the rear electrode 20 formed of molybdenum (Mo) thin film significantly enhances sodium (Na) diffusion through highly dense bulk Mo as demonstrated by the experiment, the surface of molybdenum having a dense microstructure is oxidized.

The oxidation is carried out by heat treatment using Rapid Thermal Annealing (RTA) under oxygen atmosphere, or by surface treatment with oxygen plasma under vacuum. As shown in FIG. 4, in the case of molybdenum (Mo) having a dense microstructure at as-deposited state, the sodium (Na) concentration in the CIGS thin film is relatively low. However, such oxidation of the dense molybdenum (Mo) thin film increases the sodium (Na) concentration in the CIGS thin film and also increases the sodium (Na) concentration at the CIGS/Mo interface.

The above result demonstrates that oxygen (O) adsorbed on the surface of the molybdenum (Mo) thin film is a critical factor stimulating diffusion of sodium (Na). It is thought that since sodium (Na) has high chemical affinity with oxygen (O), oxygen (O) present on the surface draws the sodium (Na) contained in the rear electrode 20 toward the surface to form high-capacity sodium (Na) depot which may serve as a sodium (Na) source for the CIGS thin film.

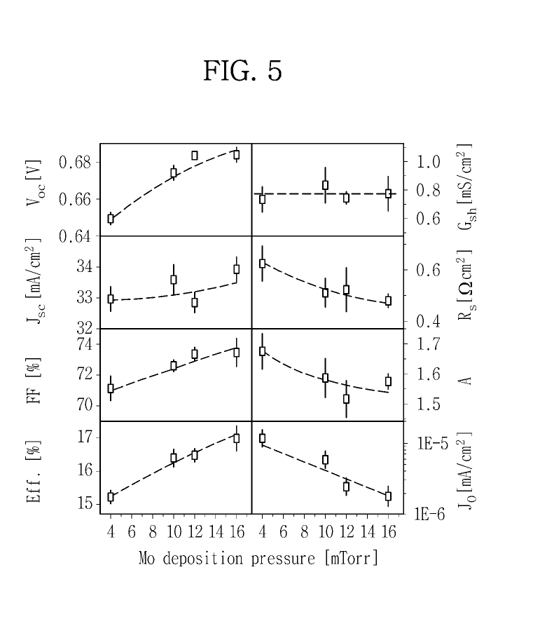

FIG. 5 is a graph illustrating photovoltaic conversion efficiency of CIGS thin film solar cell depending on surface microstructures of a rear electrode of FIG. 1.

Controlling sodium (Na) content through a change in microstructure or surface layer of a molybdenum (Mo) thin film deserves to be considered because such a change in sodium (Na) content leads to a variation in cell efficiency of a CIGS thin film solar cell. For this purpose, it is required to develop the structure of a rear electrode 20 that allows for the practical application of a technique of controlling the microstructure of a molybdenum (Mo) thin film to commercial CIGS PV modules.

To stimulate sodium (Na) diffusion, it is necessary to increase oxygen (O) present inside a molybdenum (Mo) thin film. This results in a drop in electrical conductivity of a molybdenum (Mo) thin film. Therefore, only the microstructure of the surface layer of a molybdenum (Mo) thin film is changed to increase sodium (Na) diffusion while not adversely affecting the characteristics of an electrically conductive layer.

FIG. 5 shows the results of comparison of cell efficiency among CIGS solar cells employing varying Mo surface properties, obtained by varying deposition pressure of a top layer to convert its microstructure from a dense structure to a highly porous structure. Herein, the CIGS thin film is deposited by a three-stage coevaporation process, CdS is deposited as a buffer layer, i-ZnO and Al-doped ZnO thin films are deposited as semiconductor layers (window layers), and then a Ni/Al grid layer is formed.

It can be seen that cell efficiency increases as the porosity of the microstructure of the top layer of a molybdenum (Mo) thin film increases. An increased open-circuit voltage (Voc) and fill factor (FF) are main factors of the improvement of cell efficiency. This is the same as the typical effect of increased sodium (Na) doping. To electrically evaluate the degree of sodium (Na) doping, capacitance vs. voltage (CV) profiling or drive-level capacitance profiling (DLCP) is applied. Then, it can be seen that as the porosity of the microstructure of the top layer of a molybdenum (Mo) thin film increases, carrier concentration also increases.

Therefore, it is possible to increase sodium (Na) diffusion, and thus to increase photovoltaic conversion efficiency by converting the surface of a molybdenum (Mo) thin film into highly porous, while not adversely affecting the characteristics of the rear electrode 20.

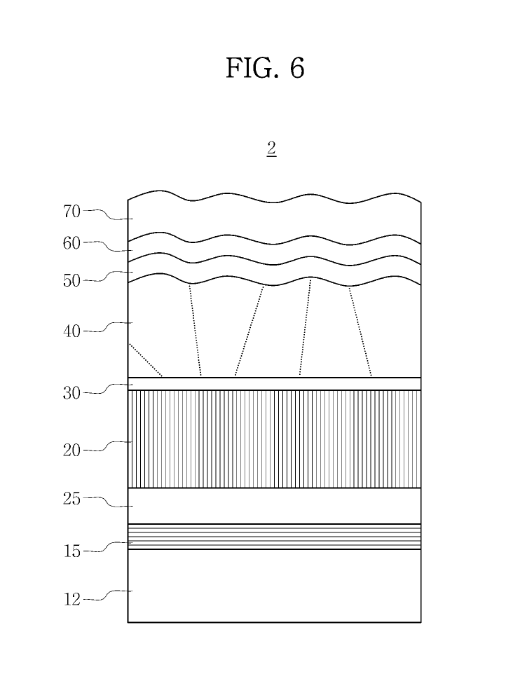

FIG. 6 is a sectional view of a thin film solar cell according to another embodiment.

Referring to FIG. 6, the thin film solar cell 2 according to another embodiment is a Se- or S-based thin film solar cell, and includes a substrate 12, a diffusion barrier film 15, a sodium (Na) precursor layer 25, a rear electrode 20, a rear electrode top layer 30 and a light absorbing layer 40, stacked successively.

The thin film solar cell 2 may further include a first semiconductor layer 50, a second semiconductor layer 60 and a transparent electrode layer 70, stacked on the light absorbing layer 40.

The thin film solar cell 2 is substantially the same as the thin film solar cell 1 as shown in FIG. 1 except the substrate 12, the diffusion barrier film 15 and the sodium (Na) precursor layer 25. Therefore, the same reference numerals denote the same elements in FIG. 1 and FIG. 6, and the detailed description of the same elements will be omitted.

The substrate 12 has flexibility and may be formed of a metal or polymer. For example, the substrate 12 may include a metal such as stainless steel or titanium (Ti). In this case, since the substrate 12 has no sodium (Na), a separate sodium (Na) source is required.

The diffusion barrier film 15 serves to prevent diffusion of impurities from the substrate 12 and to make the substrate 12 insulated electrically. The diffusion barrier film 15 may be formed of any one selected from silicon oxide (SiOₓ), aluminum oxide (Al₂O₃), chrome (Cr), zinc oxide (ZnO) and nitride thin films.

The sodium (Na) precursor layer 25 serves to supply sodium (Na) to the rear electrode 20, and may be formed of any one selected from Na-doped molybdenum (Mo), sodium fluoride (NaF), soda lime glass thin films, and alkali silicate glass thin films.

The sodium (Na) contained in the sodium (Na) precursor layer 25 subsequently passes through the rear electrode 20 during the deposition of the light absorbing layer 40 at high temperature, and then diffuses into the light absorbing layer 40.

According to the Se- or S-based thin film solar cell and the method for manufacturing the same disclosed herein, the rear electrode top layer 30 formed on the rear electrode 20 has a microstructure with high porosity, and thus is capable of stimulating sodium (Na) diffusion. Furthermore, the rear electrode 20 is formed to have a dense microstructure, and thus may have excellent electrical conductivity and, better interfacial adhesion, if stress-relaxing buffer layer is further employed. In addition, since the rear electrode 20 has a dense microstructure, it is possible to ensure stability at high temperature and to ensure uniformity in sodium (Na) diffusion.

CIGS thin film solar cells have high ability of light absorption, excellent carrier transport properties, high photovoltaic conversion efficiency, and low cost manufacturability, derived from application of an economical thin film process. Thus, CIGS thin film solar cells have already been commercialized and have been expected to get increased importance in the solar cell market.

The thin film solar cell including a rear electrode top layer disclosed herein allows independent control of diffusion of sodium (Na) ions that have a predominant effect upon the efficiency of a module, while reinforcing the other functions of a rear electrode such as electrical conduction and mechanical stability. Therefore, the thin film solar cell disclosed herein is capable of independently improving the electrical properties of a CIGS-based light absorbing layer.

In addition, the thin film solar cell disclosed herein is capable of improving performance uniformity of large-area modules and contributes to improvement of efficiency of commercialized modules of CIGS thin film solar cells, thereby improving cost competiveness of commercially available solar cell modules.

While the exemplary embodiments have been shown and described, it will be understood by those skilled in the art that various changes in form and details may be made thereto without departing from the spirit and scope of the present disclosure as defined by the appended claims.

What is claimed is:

1. A Se- or S-based thin film solar cell, comprising:
a substrate;
a rear electrode formed on the substrate;
a light absorbing layer formed on the rear electrode and containing at least one of selenium (Se) and sulfur (S); and
a rear electrode top layer formed between the rear electrode and the light absorbing layer and containing oxygen (O) to control diffusion of sodium (Na) from the rear electrode to the light absorbing layer.

2. The Se- or S-based thin film solar cell according to claim 1, wherein the rear electrode has a dense microstructure by application of high compressive residual stress thereto, and the rear electrode top layer has a microstructure with higher porosity than the rear electrode, wherein the porosity may be 0.1-20%.

3. The Se- or S-based thin film solar cell according to claim 1, wherein the rear electrode has a dense microstructure by application of high compressive residual stress thereto, and the rear electrode top layer has an oxygen content of 1-20 at %.

4. The Se- or S-based thin film solar cell according to claim 1, wherein the rear electrode top layer has a higher sodium (Na) content than the rear electrode.

5. The Se- or S-based thin film solar cell according to claim 1, wherein the light absorbing layer comprises any one of Cu(In₁₋ₓ,Gaₓ)(Se,S)₂ (CIGS) as a I-III-VI₂ semiconductor compound and Cu₂ZnSn(Se,S)₄ (CZTS) as a I₂-II-IV-VI₄ semiconductor compound.

6. The Se- or S-based thin film solar cell according to claim 1, wherein the rear electrode top layer comprises a metal (M) that reacts with selenium (Se) of the light absorbing layer to form a compound of MₓSe_{y}.

7. The Se- or S-based thin film solar cell according to claim 1, wherein the rear electrode or the rear electrode top layer comprises any one of molybdenum (Mo), nickel (Ni), tungsten (W), cobalt (Co), titanium (Ti), copper (Cu) and gold (Au), or an alloy thereof.

8. The Se- or S-based thin film solar cell according to claim 1, wherein the rear electrode is in a single layer or bilayer.

9. The Se- or S-based thin film solar cell according to claim 1, wherein the substrate is formed of any one of transparent insulating materials, metals and polymers.

10. The Se- or S-based thin film solar cell according to claim 9, wherein the substrate comprises a metal, such as stainless steel or titanium (Ti), and which further comprises a diffusion barrier film and a sodium (Na) precursor layer between the substrate and the rear electrode.

11. The Se- or S-based thin film solar cell according to claim 10, wherein the diffusion barrier film is formed of any one selected from silicon oxide (SiOₓ), aluminum oxide (Al₂O₃), chrome (Cr), zinc oxide (ZnO) and nitride thin films.

12. The Se- or S-based thin film solar cell according to claim 10, wherein the sodium (Na) precursor layer is formed of any one selected from sodium (Na)-doped molybdenum (Mo), sodium fluoride (NaF), soda lime glass thin films, and alkali silicate glass thin films.

13. The Se- or S-based thin film solar cell according to claim 1, which further comprises a first semiconductor layer, a second semiconductor layer and a transparent electrode layer formed on the light absorbing layer.

14. A method for manufacturing a Se- or S-based thin film solar cell, comprising:
forming a rear electrode on a substrate;
forming an rear electrode top layer containing oxygen (O) on the rear electrode; and
forming a light absorbing layer containing at least one of selenium (Se) and sulfur (S) on the rear electrode top layer.

15. The method for manufacturing a Se- or S-based thin film solar cell according to claim 14, wherein said forming an rear electrode top layer is carried out by depositing a molybdenum (Mo) thin film having a porosity of 0.1-20% so that the rear electrode top layer has a microstructure with higher porosity than the rear electrode.

16. The method for manufacturing a Se- or S-based thin film solar cell according to claim 14, wherein said forming a rear electrode top layer is carried out under argon atmosphere of 8-40 mTorr to a thickness of 1-50 nm.

17. The method for manufacturing a Se- or S-based thin film solar cell according to claim 14, wherein said forming a rear electrode top layer is carried out by oxidizing the surface of the rear electrode.

18. The method for manufacturing a Se- or S-based thin film solar cell according to claim 17, wherein the rear electrode is exposed to oxygen plasma under vacuum to oxidize the surface of the rear electrode.

19. The method for manufacturing a Se- or S-based thin film solar cell according to claim 17, wherein the rear electrode is subjected to heat treatment under oxygen atmosphere to oxidize the surface of the rear electrode.

20. The method for manufacturing a Se- or S-based thin film solar cell according to claim 14, wherein said forming a rear electrode further comprises forming a stress-relaxing buffer layer on the substrate.

21. The method for manufacturing a Se- or S-based thin film solar cell according to claim 14, which further comprises, when the substrate comprises a metal:
forming a diffusion barrier film on the substrate; and
forming a sodium (Na) precursor layer on the diffusion barrier film,
before said forming the rear electrode.

22. The method for manufacturing a Se- or S-based thin film solar cell according to claim 14, which further comprises stacking a first semiconductor layer, and a second semiconductor layer and a transparent electrode layer sequentially on the light absorbing layer.
